(19) United States
(12) Patent Application Publication
(10) Pub. No.: US 2007/0111405 A1
(43) Pub. Date: May 17, 2007

(54) Design method for semiconductor integrated circuit

(76) Inventors: Shinji Watanabe, Osaka (JP); Kyoji Yamashita, Kyoto (JP); Katsuhiro Ootani, Nara (JP)

Correspondence Address: MCDERMOTT WILL & EMERY LLP, 600 13TH STREET, N.W., WASHINGTON, DC, 20005-3096, US

(21) Appl. No.: 11/518,199

(22) Filed: Sep. 11, 2006

(30) Foreign Application Priority Data
Nov. 15, 2005 (JP) 2005-330757

(51) Int. Cl. H01L 21/8232; H01L 21/335

(52) U.S. Cl. 438/142

(57) ABSTRACT

In a standard cell in which an active area and a gate conductor are provided, the active area has a largest length in a gate width direction at an end thereof in a gate length direction.

### BACKGROUND OF THE INVENTION

1. Field of the Invention

The present invention relates to a design method for a semiconductor integrated circuit having a number of MIS transistors.

2. Description of the Related Art

In recent years, there is a demand for a further improvement in simulation accuracy of circuit simulators for the development of system LSIs and the like. As the level of miniaturization of semiconductor processes is increased, the performance of simulation is more significantly affected by the layout pattern, arrangement or the like of circuit elements. Particularly, in transistors having an isolation insulating film, such as STI (Shallow Trench Isolation) or the like, attention has been paid to a phenomenon that the mobility of a channel changes due to mechanical stress applied from the isolation insulating film to the transistor, which is considered as a factor of inhibiting an improvement in accuracy of circuit simulation.

In conventional circuit simulation techniques, there is not a parameter which allows for stress applied from an isolation insulating film to a transistor, so that the same parameters are used with respect to transistors which have the same size and to which different stresses are applied so as to execute circuit simulation. Therefore, a difference in characteristics due to stress is included as an error, so that it is difficult to perform accurate circuit simulation.

To solve such a problem, a technique has been proposed in which circuit simulation is executed while stress from an isolation insulating film to a transistor is defined as a parameter, thereby improving accuracy (see, for example, JP 2003-264242 A (Patent Document 1) and JP 2004-86546 A (Patent Document 2)). As an index for stress applied to a transistor, Patent Document 1 defines a length of an active area, and Patent Document 2 defines a width of an isolation insulating film, for execution of circuit simulation.

FIG. 5 is a plan view for explaining parameters of general circuit simulation. Note that a semiconductor device illustrated in FIG. 5 is disclosed in Patent Document 2.

In the conventional semiconductor device of FIG. 5, an active area 102, and an isolation area 101 laterally surrounding the active area 102 are provided on a semiconductor substrate 100. A gate electrode 103 is provided on the active area 102. In the semiconductor device, major factors which are considered as indexes for stress during simulation are widths ODFL and ODFR of portions of the active area 102 provided on left and right sides of the gate electrode 103, respectively; widths ODSL and ODSR in a gate length direction of the isolation area 101; and widths ODSU and ODSD in a gate width direction of the isolation area 101, as well as a gate length L1 and a gate width W1 (transistor dimensions). Of these indexes, the widths ODFL and ODFR are collectively referred to as an OD finger, and the widths ODSL, ODSR, ODSU and ODSD are collectively referred to as an OD separate.

Even for a semiconductor device having the same transistor size, optimal model parameters are selected using several kinds of model parameters classified into the OD finger and the OD separate, and the optimal model parameters are used to execute circuit simulation, thereby improving simulation accuracy. Thereby, it is possible to use a simulation result suitable for design for miniaturized circuits.

Recent system LSIs are designed by a cell-based technique. FIG. 6 is a plan view illustrating an exemplary conventional cell of a system LSI. Transistors are arranged in a cell in a manner which varies depending on the function and application of a logic circuit which is constructed with the cell. A system LSI is designed by combining a plurality of cells, such as that illustrated in FIG. 6.

In the conventional cell of FIG. 6, P-type active areas 114 and 115 and an N-type substrate contact area 119 are provided in an N-type well 112 formed on a semiconductor substrate 111. Also, N-type active areas 116 and 117 and a P-type substrate contact area 120 are provided in a P-type well 113 formed on the semiconductor substrate 111. Note that, in FIG. 6, a boundary between cells is indicated by a dashed line. Gate conductors 121 to 125 are formed on the P-type active areas 114 and 115 and the N-type active areas 116 and 117. These parts constitute N-type transistors NTr0, NTr1, NTr2, NTr3 and NTr4 and P-type transistors PTr0, PTr1, PTr2, PTr3 and PTr4.

Dummy gate electrodes 126, 127 and 128 are provided in portions located on the N-type well 112 and the P-type well 113 of the semiconductor substrate 111.

In the cell of FIG. 6, gate widths of the N-type transistors NTr0 to NTr4 are indicated by Wn0 to Wn4, respectively, and gate widths of the P-type transistors PTr0 to PTr4 are indicated by Wp0 to Wp4, respectively.

### SUMMARY OF THE INVENTION

However, even when the above-described conventional method is used to perform simulation, a sufficient level of accuracy cannot be obtained.

Therefore, an object of the present invention is to provide a semiconductor integrated circuit designing method capable of performing simulation with high accuracy.

A method according to an embodiment of the present invention is provided for designing a semiconductor integrated circuit comprising a first cell in which MIS transistors having different gate widths are arranged in a gate length direction. The first cell comprises, at least, a first active area provided in a portion closer to one end of the first cell and a second active area provided in a portion closer to the other end of the first cell, in a gate length direction. The method comprises causing the first active area and the second active area to have the same length in a gate width direction, and causing the length to be largest of those of a plurality of active areas provided in the gate length direction in the first cell.

According to the semiconductor integrated circuit designing method of the embodiment of the present invention, a distance between active areas can be caused to be constant between the first cell and surrounding cells. Thereby, it is possible to cause an influence of stress due to an adjacent cell to be constant. In this case, it is possible to predict the influence of stress caused by an adjacent cell, whereby only one standard cell can be used to perform simulation, taking into consideration the influence of an adjacent standard cell. Thereby, simulation accuracy can be improved. Particularly, it is possible to improve the accuracy of simulation which employs a cell library, which is currently a major stream.

The first cell may further comprise a third active area provided between the first active area and the second active area. The method may further comprise causing a length in the gate width direction of the third active area to be smaller than the length in the gate width direction of the first active area and the second active area.

The method may further comprise arranging the third active area adjacent to the first active area.

The method may further comprise arranging the second active area distant from the third active area.

The method may further comprise arranging the second active area adjacent to the third active area.

The semiconductor integrated circuit may further comprise a second cell at least including a semiconductor area in a portion closer to an end thereof. The method may further comprise causing a length and a position in the gate width direction of the semiconductor area to be the same as those of the first active area and the second active area, and arranging the second cell adjacent to at least one of both ends in the gate length direction of the first cell.

The method may further comprise causing a distance between the semiconductor area and the first or second active area facing the semiconductor area to be constant.

The second cell may be a spacer cell which does not have an MIS transistor, and the semiconductor area may be a dummy active area.

In this case, the method may further comprise adjusting a size of the spacer cell so that the dummy active area can be provided in the spacer cell.

The second cell may be a cell having an MIS transistor, and the semiconductor area may be an active area.

The method may further comprise causing a distance from a boundary between the first cell and the second cell to the semiconductor area to be the same as a distance from the boundary to the first or second active area facing the semiconductor area.

The first active area, the second active area, and the semiconductor area may have the same conductivity-type impurity area.

### BRIEF DESCRIPTION OF THE DRAWINGS

FIG. 1 is a plan view illustrating a structure of a standard cell according to a first embodiment of the present invention.

FIG. 2 is a plan view illustrating a structure in which two standard cells of FIG. 1 are arranged side by side.

FIG. 3 is a plan view illustrating a variation of the first embodiment.

FIG. 4 is a plan view illustrating a structure of a standard cell according to a second embodiment of the present invention.

FIG. 5 is a plan view for explaining parameters of general circuit simulation.

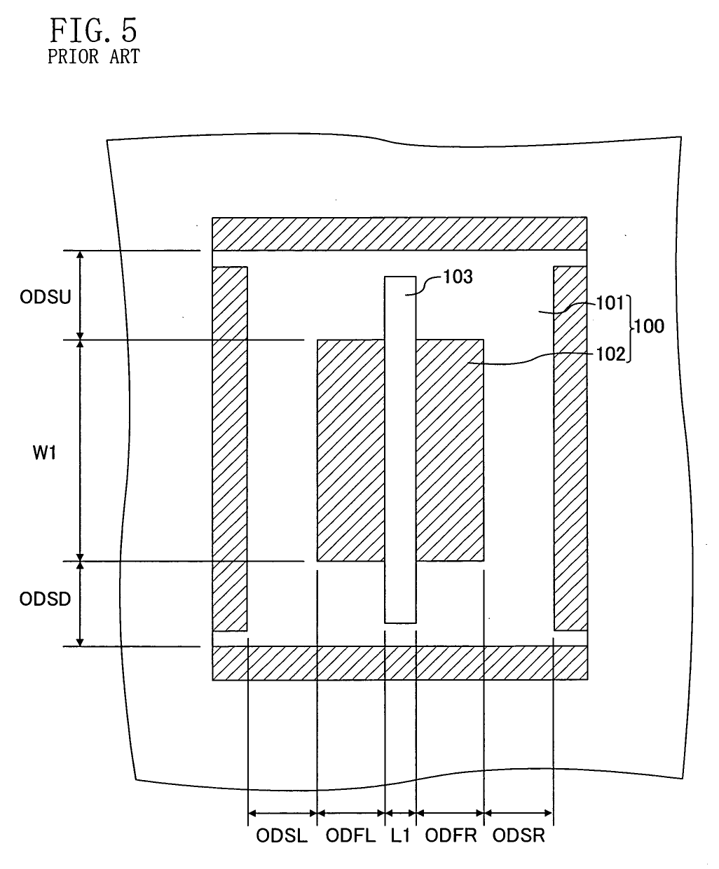

FIG. 6 is a plan view illustrating an exemplary conventional cell of a system LSI.

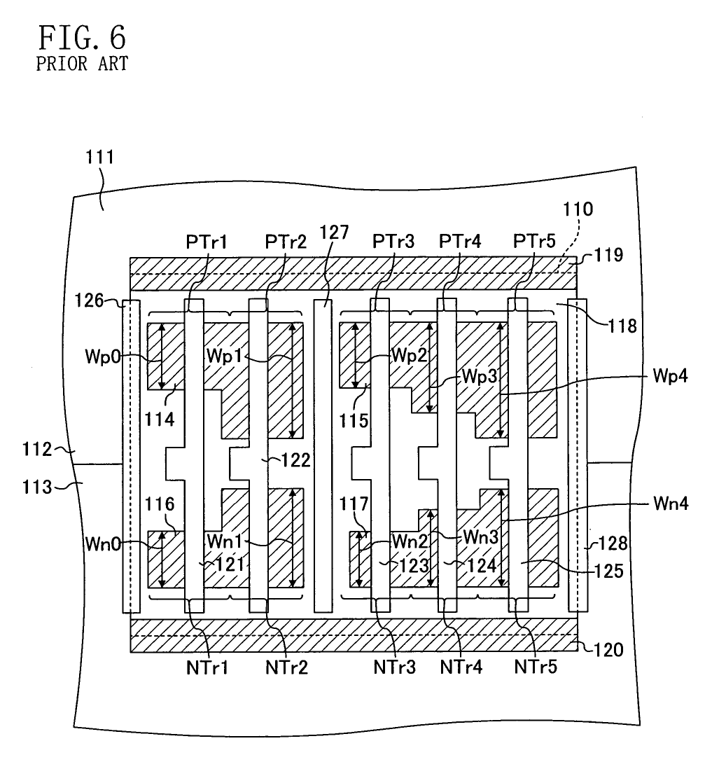

FIGS. 7A and 7B are plan views illustrating arrays in which a plurality of cells are arranged.

### DETAILED DESCRIPTION OF THE PREFFERED EMBODYMENTS

(Inventors' Consideration)

The inventors consider why simulation accuracy cannot be increased in the conventional art, as follows.

Conventional documents disclose only techniques of modeling the inside of a cell, and do not specifically disclose how to address an influence of an adjacent cell. However, since cells are arranged in an array in actual LSIs, it is considered that characteristics of a transistor in a cell vary due to an influence of an adjacent cell.

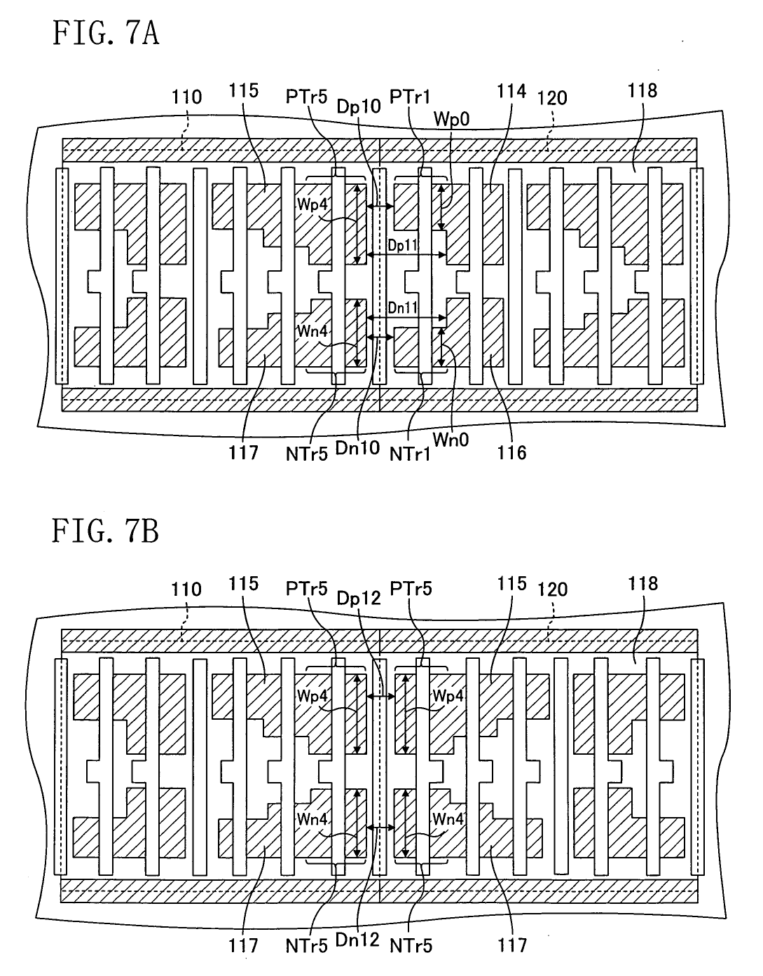

FIGS. 7A and 7B are plan views illustrating arrays in which a plurality of cells are arranged. In FIG. 7A, two cells 110 and 120 having the same arrangement are provided side by side, the two cells 110 and 120 being oriented in the same direction. In FIG. 7B, the orientation of one of the two cells 110 and 120 is reversed as compared to FIG. 7A.

Here, an effective isolation width will be described using a simple expression, giving attention to a fifth P-type MIS transistor PTr5.

In the structure of FIG. 7A, the fifth P-type MIS transistor PTr5 of the standard cell 110 is adjacent to a first P-type MIS transistor PTr1 of the standard cell 120. A width (width in a length direction in FIG. 7A) Wp4 of an active area of the fifth P-type MIS transistor PTr5 is larger than a width Wp0 of the first P-type MIS transistor PTr1. Therefore, an isolation area 118 between the fifth P-type MIS transistor PTr5 and the first P-type MIS transistor PTr1 have two widths Dp10 and Dp11. Similarly, the isolation area 118 between a fifth N-type MIS transistor NTr5 and a first N-type MIS transistor NTr1 have two widths Dn10 and Dn11. Therefore, an effective isolation width of the isolation area 118 is represented by the following simple approximate expression (1).
Dn10×Wn0/Wn4+Dn11×(Wn4−Wn0)/Wn4 (1)

On the other hand, in the structure of FIG. 7B, fifth P-type MIS transistors PTr5 are adjacent to each other in a boundary portion between the standard cell 110 and the standard cell 120. Since the active areas 115 of these fifth P-type MIS transistors PTr5 have the same width (Wp4), the isolation area 118 between the fifth P-type MIS transistors PTr5 has a uniform width Dp12. Similarly, the isolation area 118 between the fifth N-type MIS transistors NTr5 has a uniform width Dn12.

Thus, it is necessary to consider an adjacent cell as well as a standard cell of interest, and perform simulation at the chip level as well as for a single standard cell, so as to reflect an influence of stress due to an isolation insulating film on a model parameter. However, combinations of standard cells on a chip have a huge number of patterns, and it is practically difficult to perform simulation with respect to all the patterns, in terms of time and a tool.

According to the above-described consideration, the inventors created a method for specifying an influence of an adjacent standard cell by performing simulation with respect to only a standard cell.

### First Embodiment

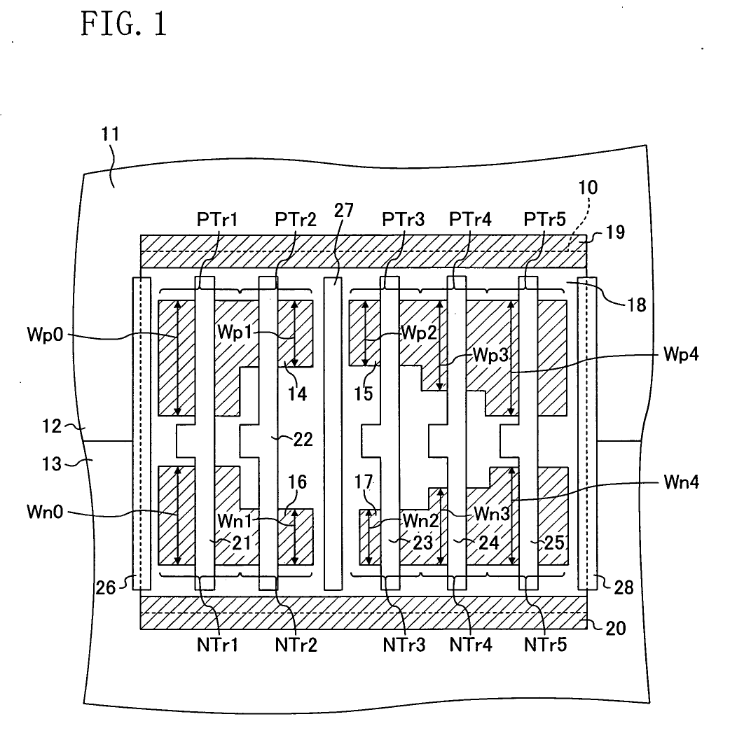

Hereinafter, a semiconductor circuit device designing method according to a first embodiment of the present invention will be described with reference to the accompanying drawings. FIG. 1 is a plan view illustrating a structure of a standard cell according to the first embodiment of the present invention. Note that the standard cell (or cell) as used herein refers to a range within which CMIS transistors are arranged and connected so as to achieve one or more functions (e.g., logical inversion, logical AND, etc.). A system LSI is designed by providing several hundreds of kinds of standard cells and performing wiring between the standard cells. In general, simulation is performed with respect to a system LSI using a hierarchy. For each of the several hundreds of kinds of standard cells, simulation is performed to create a table of delay information, and the delay information is used to perform simulation at the block level and the chip level.

In FIG. 1, a boundary between each standard cell is indicated by a dashed line. In the standard cell 10 of this embodiment, an N-type well 12 and a P-type well 13 are provided on a semiconductor substrate 11. Also, in the standard cell 10, active areas 14, 15, 16 and 17, and an isolation area 18 surrounding the active areas 14, 15, 16 and 17 are provided. Here, P-type impurity areas (P-type source and drain areas) are provided left and right sides of gate conductors 21 to 25 in the active areas 14 and 15, and N-type impurity areas (N-type source and drain areas) are provided on left and right sides of the gate conductors 21 to 25 in the active areas 16 and 17.

Regarding the active area 14, a width Wp0 (length in a gate width direction) of a side closer to the outside of the standard cell 10 is larger than a width Wp1 of a side farther inside the standard cell 10.

Regarding the active area 15, a length in the gate width direction is gradually increased toward the outside of the standard cell 10. Specifically, widths Wp2, Wp3 and Wp4 are provided successively toward the outside of the standard cell 10. The widths adjacent to each other (i.e., Wp1 and Wp2) of the active area 14 and the active area 15 are the same as each other.

Regarding the active area 16, a width (gate width) Wn0 of a side closer to the outside of the standard cell 10 is larger than a width Wn1 of a side farther inside the standard cell 10.

Regarding the active area 17, a length in the gate width direction is gradually increased toward the outside of the standard cell 10. Specifically, widths Wn2, Wn3 and Wn4 are provided successively toward the outside of the standard cell 10. The widths adjacent to each other (i.e., Wn1 and Wn2) of the active area 16 and the active area 17 are the same as each other.

The gate conductors 21 to 25 are provided on the semiconductor substrate 11. Note that the gate conductors 21 to 25 function as gate electrodes on the active areas 14 to 17. The gate conductor 21 is formed, extending over from a portion having the width Wp0 of the active area 14 to a portion having the width Wn0 of the active area 16. The gate conductor 21 and the active area 14 constitute a first P-type MIS transistor PTr1, and the gate conductor 21 and the active area 16 constitute a first N-type MIS transistor NTr1. Also, the gate conductor 22 is formed, extending over from a portion having the width Wp1 of the active area 14 to a portion having the width Wn1 of the active area 16. The gate conductor 22 and the active area 14 constitute a second P-type MIS transistor PTr2, and the gate conductor 22 and the active area 16 constitute a second N-type MIS transistor NTr2. Also, the gate conductor. 23 is formed, extending over from a portion having the width Wp2 of the active area 15 to a portion having the width Wn2 of the active area 17. The gate conductor 23 and the active area 15 constitute a third P-type MIS transistor PTr3, and the gate conductor 23 and the active area 17 constitute a third N-type MIS transistor NTr3. Also, the gate conductor 24 is formed, extending over from a portion having the width Wp3 of the active area 15 to a portion having the width Wn3 of the active area 17. The gate conductor 24 and the active area 15 constitute a fourth P-type MIS transistor PTr4, and the gate conductor 24 and the active area 17 constitute a fourth N-type MIS transistor NTr4. Also, the gate conductor 25 is formed, extending over from a portion having width Wp4 of the active area 15 to a portion having the width Wn4 of the active area 17. The gate conductor 25 and the active area 15 constitute a fifth P-type MIS transistor PTr5, and the gate conductor 25 and the active area 17 constitute a fifth N-type MIS transistor NTr5.

An N-type substrate contact area 19 having an N-type impurity is formed in a portion above the active areas 14 and 15 of the boundary portion of the standard cell 10. The N-type substrate contact area 19 is laterally surrounded by the isolation area 18. On the other hand, a P-type substrate contact area 20 having a P-type impurity is formed in a portion below the active areas 16 and 17 of the boundary portion of the standard cell 10. The P-type substrate contact area 20 is laterally surrounded by the isolation area 18.

A dummy gate electrode 26 is formed on a portion lateral (left) to the active areas 14 and 16 of the isolation area 18. The dummy gate electrode 26 has the same length as that of the gate conductor 21. A dummy gate electrode 27 is formed on a portion between the active area 14 and the active area 15 of the isolation area 18 and on a portion between the active area 16 and the active area 17 of the isolation area 18. A dummy gate electrode 28 is formed on a portion lateral (right) to the active areas 15 and 17 of the isolation area 18.

In the standard cell 10 of FIG. 1, each of the active areas 14 to 17 have a largest length in the gate width direction at an end portion in the gate length direction of the standard cell 10. In other words, regarding each of the active areas 14 to 17, the length closer the outside of the standard cell 10 is larger than the length closer to the center of the standard cell 10.

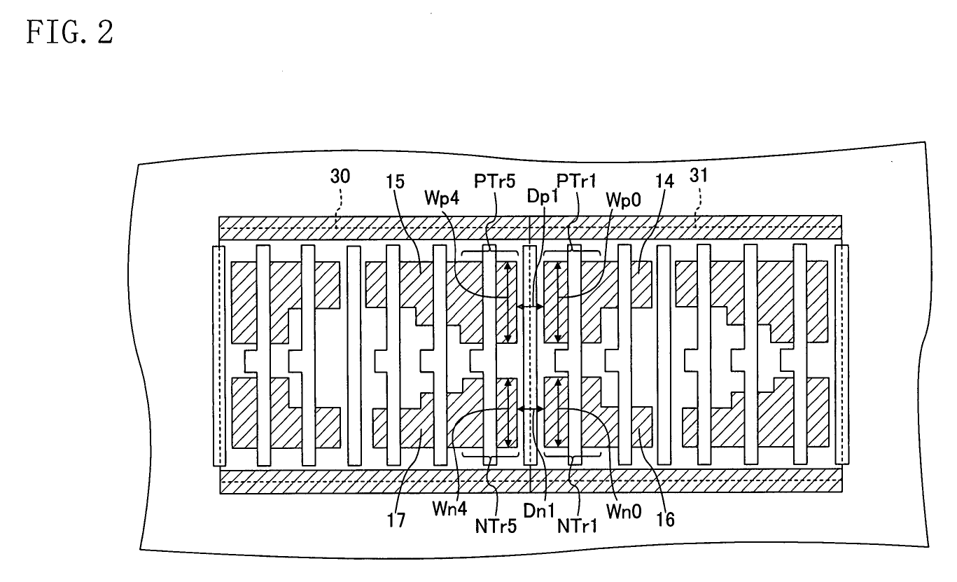

FIG. 2 is a plan view illustrating a structure in which two standard cells of FIG. 1 are arranged side by side. In the structure of FIG. 2, standard cells 30 and 31 having the same structure are provided adjacent to each other. The width Wp4 of a portion closest to the standard cell 31 of the active area 15 of the standard cell 30 is the same as the width Wp0 of a portion closest to the standard cell 30 of the active area 14 of the standard cell 31. Also, the P-type MIS transistor PTr5 and the N-type MIS transistor NTr5 at a right end of the standard cell 30 and the P-type MIS transistor PTr1 and the N-type MIS transistor NTr1 at a left end of the standard cell 31, respectively, coincide with each other in the gate width direction. Also, a distance Dp1 from the active area 15 in the standard cell 30 to the active area 14 in the standard cell 31 is the same as a distance Dn1 from the active area 17 in the standard cell 30 to the active area 16 in the standard cell 31. Note that the width Dp1 and the width Dn1 are a constant value. Also, a distance from a boundary between the standard cell 30 and the standard cell 31 to the active area 15 in the standard cell 30 is the same as a distance from the boundary to the active area 14 in the standard cell 31.

In this embodiment, the active areas in each standard cell have the same and largest length in the gate width direction at both end portions thereof in the gate length direction, whereby the distance between the active areas can be caused to be constant between each standard cell. Thereby, an influence of stress caused by an adjacent cell can be caused to be constant. In this case, it is possible to predict the influence of stress caused by an adjacent cell, whereby only one standard cell can be used to perform simulation, taking into consideration the influence of an adjacent standard cell. Thereby, simulation accuracy can be improved. Particularly, it is possible to improve the accuracy of simulation which employs a cell library, which is currently a major stream.

Although the case where two standard cells having the same structure are arranged side by side has been described in FIG. 2, the present invention is also applicable when standard cells having different structures are provided adjacent to each other. Also in this case, a similar effect can be obtained by providing settings as described above.

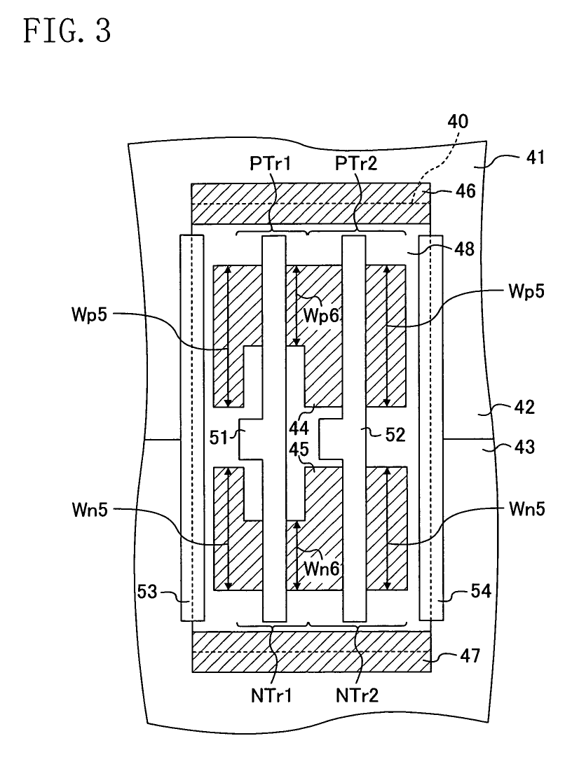

In the structures of FIGS. 1 and 2, a transistor having the largest gate width is provided at an end of a standard cell, so that the length in the gate width direction of the active area at the end of the standard cell is largest. However, there may be a case where a transistor having the largest gate width cannot be provided at an end of a standard cell. Such a case will be described with reference to FIG. 3.

FIG. 3 is a plan view illustrating a variation of the first embodiment. In a structure of FIG. 3, an N-type well 42 and a P-type well 43 are provided on a semiconductor substrate 41. An isolation area 48 is formed in the N-type well 42 and the P-type well 43. In the isolation area 48, an active area 44 having a P-type impurity area and an active area 45 having an N-type impurity area are provided. Gate conductors 51 and 52 are formed, extending over from the active area 44 to the active area 45. The active area 44 has two widths Wp5 and Wp6. The active area 44 has the width Wp5 at both ends thereof, and has the width Wp6, which is smaller than the width Wp5, at a portion excluding both the ends thereof. On the other hand, the active area 45 has a width Wn5 at both ends thereof, and has a width Wn6, which is smaller than the width Wn5, at a portion excluding both the ends thereof. The gate conductor 51 is formed, extending over from a portion having the width Wp6 of the active area 44, to a portion having the width Wn6 of the active area 45. On the other hand, the gate conductor 52 is formed, extending over from a portion having the width Wp5 of the active area 44, to a portion having the width Wn5 of the active area 45. The gate conductor 51 and the active area 44 constitute a first P-type MIS transistor PTr1, and the gate conductor 52 and active area 44 constitute a second P-type MIS transistor PTr2. On the other hand, the gate conductor 51 and the active area 45 constitute a first N-type MIS transistor NTr1, and the gate conductor 52 and the active area 45 constitute a second N-type MIS transistor NTr2.

In the structure of FIG. 3, the width Wp5 of the left end portion of the active area 44 is larger than the gate width Wp6 of the first P-type MIS transistor PTr1, and the width Wn5 of the left end portion of the active area 45 is larger than the gate width Wn6 of the first N-type MIS transistor NTr1. In other words, although the widths Wp6 and Wn6 of the left end portions of the active areas 44 and 45 are sufficient to secure the gate widths of the first P-type MIS transistor PTr1 and the first N-type MIS transistor NTr1, this variation is provided with the widths Wp5 and Wn5, which are larger than the widths Wp6 and Wn6. An N-type substrate contact area 46 including an N-type impurity is formed in a portion located above the active area 44 of a boundary portion of a standard cell 40. The N-type substrate contact area 46 is laterally surrounded by the isolation area 48. On the other hand, a P-type substrate contact area 47 including a P-type impurity is formed in a portion located below the active area 45 of the boundary portion of the standard cell 40. The P-type substrate contact area 47 is laterally surrounded by the isolation area 48.

A dummy gate electrode 53 is formed on a portion lateral (left) to the active areas 44 and 45 of the isolation area 48. The dummy gate electrode 53 has the same length as that of the gate conductor 51. A dummy gate electrode 54 is formed on a portion lateral (right) to the active areas 44 and 45 of the isolation area 48.

In this variation, even when a transistor having the largest gate width cannot be provided at an end of a standard cell, by maximizing the width of an active area at an end of a standard cell, an influence of stress on an adjacent standard cell can be caused to be at a level which can be simulated. Specifically, in the structure of FIG. 3, by causing the width at the left end of the active area 44 to be Wp5, the effective width of the channel of the first P-type MIS transistor PTr1 is increased. However, a change in characteristics due to the increase of the width can be modeled, thereby making it possible to obtain a more accurate simulation result.

### Second Embodiment

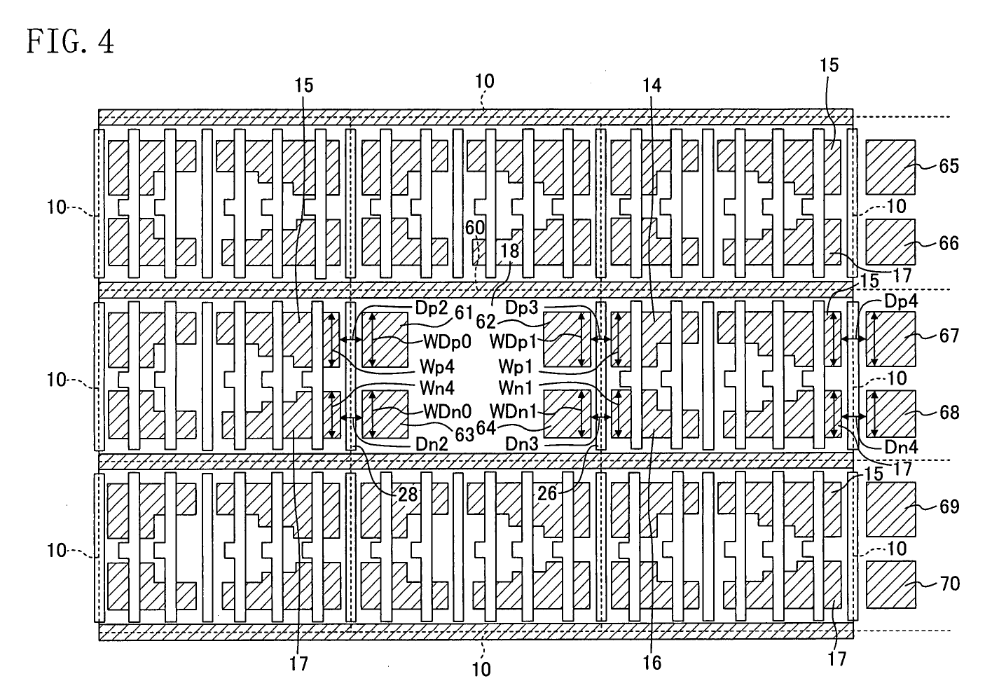

Hereinafter, a semiconductor circuit device designing method according to a second embodiment of the present invention will be described with reference to the drawings. FIG. 4 is a plan view illustrating a structure of a standard cell according to a second embodiment of the present invention. In the structure of FIG. 4, a plurality of the standard cells 10 of FIG. 1 are arranged in an array.

In FIG. 4, a boundary between each standard cell 10 is indicated by a dashed line. Note that an arrangement of gate conductors and active areas in the standard cell 10 is similar to that of FIG. 1, and will not be described in detail.

At the present time, LSIs are generally designed using a cell-based technique. In this method, cells are provided at lattice points, and input and output terminals (not shown) in the standard cell 10 are connected using conductors (not shown). This design is automatically performed using an EDA tool (tool for arranging cells and connecting the cells using conductors).

Since there are various kinds of standard cells and conductors, it is difficult to lay out standard cells and conductors without leaving a space. Therefore, as illustrated in FIG. 4, there is a spacer cell 60 in which a standard cell 10 cannot be provided. In the spacer cell 60, an isolation area 18 and dummy active areas 61, 62, 63 and 64 are provided. Widths in the gate width direction (the length direction in FIG. 4) of the dummy active areas 61, 62, 63 and 64 are the same as those of the active areas 14, 15, 16 and 17 of an adjacent standard cell 10, respectively.

Also, the dummy active areas 61 and 62 coincide with the active areas 15 and 14, respectively, in the gate width direction. On the other hand, the dummy active areas 63 and 64 coincide with the active areas 17 and 16, respectively, in the gate width direction. Also, a distance Dp2 from the active area 15 to the dummy active area 61, a distance Dp3 from the active area 14 and the dummy active area 62, a distance Dn2 from the active area 17 to the dummy active area 63, and a distance Dn3 from the active area 16 to the dummy active area 64 have the same value.

Note that the dummy active areas 61 to 64 may be arranged using the EDA tool, or alternatively, cells in which dummy active areas are previously formed are prepared, and the cell width may be set to be an integral multiple of a lattice point. In general design rules, a dummy active area can be provided even in a smallest free space, however, a dummy diffusion area may not be provided, depending on the design rule. In such a case, a function of forbidding a space having a small space width may be added to the EDA tool for arranging cells. Specifically, if a space having a small space width is likely to occur in a middle portion of an array, both standard cells adjacent thereto may be arranged closer to each other so as to eliminate the space, or conversely, both the adjacent standard cells are arranged more distant to each other so as to provide a space in which an active area can be provided.

Also, in the structure of FIG. 4, dummy active areas 65 to 70 are provided lateral to standard cells 10 located at an end portion (right side) of the array.

A width in the gate width direction of each of the dummy active areas 65 to 70 is the same as the width of the active area 15 or 17 of the adjacent standard cell 10. Also, the dummy active areas 65, 67 and 69 coincide with the respective corresponding active areas 15 in the gate width direction. Also, the dummy active areas 66, 68 and 70 coincide with the respective corresponding active areas 17 in the gate width direction. A distance Dp4 from the dummy active areas 65, 67 and 69 to the respective corresponding active areas 15 and a distance Dn4 from the dummy active areas 66, 68 and 70 to the respective corresponding active areas 17 have the same value. Note that the distances Dp4 and Dn4 and the distances Dp2, Dp3, Dn2 and Dn3 have the same value.

Note that the dummy active areas 65 to 70 may be arranged using the EDA tool, or alternatively, cells in which dummy active areas are previously formed are prepared, and the cells may be arranged in a peripheral portion of an array.

In this embodiment, when a space occurs lateral to a standard cell, by providing a dummy active area in the space, it is possible to prevent characteristics of the standard cell from changing. Thereby, it is possible to predict the influence of stress caused by an adjacent cell, whereby only one standard cell can be used to perform simulation, taking into consideration the influence of an adjacent standard cell. Thereby, simulation accuracy can be improved. Particularly, it is possible to improve the accuracy of simulation which employs a cell library, which is currently a major stream.

Also, by providing a dummy active area lateral to a standard cell at an end of an array, it is possible to prevent characteristics of the standard cell from changing. Thereby, it is possible to predict the influence of stress caused by an adjacent cell, whereby only one standard cell can be used to perform simulation, taking into consideration the influence of an adjacent standard cell. Thereby, simulation accuracy can be improved. Particularly, it is possible to improve the accuracy of simulation which employs a cell library, which is currently a major stream.

What is claimed is:

1. A method for designing a semiconductor integrated circuit comprising a first cell in which MIS transistors having different gate widths are arranged in a gate length direction, wherein the first cell comprises, at least, a first active area provided in a portion closer to one end of the first cell and a second active area provided in a portion closer to the other end of the first cell, in a gate length direction, the method comprising:
causing the first active area and the second active area to have the same length in a gate width direction, and causing the length to be largest of those of a plurality of active areas provided in the gate length direction in the first cell.

2. The method of claim 1, wherein the first cell further comprises a third active area provided between the first active area and the second active area, and
the method further comprises:
causing a length in the gate width direction of the third active area to be smaller than the length in the gate width direction of the first active area and the second active area.

3. The method of claim 2, further comprising:
arranging the third active area adjacent to the first active area.

4. The method of claim 3, further comprising:
arranging the second active area distant from the third active area.

5. The method of claim 3, further comprising:
arranging the second active area adjacent to the third active area.

6. The method of claim 1, wherein the semiconductor integrated circuit further comprises a second cell at least including a semiconductor area in a portion closer to an end thereof, and
the method further comprises:
causing a length and a position in the gate width direction of the semiconductor area to be the same as those of the first active area and the second active area; and
arranging the second cell adjacent to at least one of both ends in the gate length direction of the first cell.

7. The method of claim 6, further comprising:
causing a distance between the semiconductor area and the first or second active area facing the semiconductor area to be constant.

8. The method of claim 6, wherein the second cell is a spacer cell which does not have an MIS transistor, and
the semiconductor area is a dummy active area.

9. The method of claim 8, further comprising:
adjusting a size of the spacer cell so that the dummy active area can be provided in the spacer cell.

10. The method of claim 6, wherein the second cell is a cell having an MIS transistor, and
the semiconductor area is an active area.

11. The method of claim 6, further comprising:
causing a distance from a boundary between the first cell and the second cell to the semiconductor area to be the same as a distance from the boundary to the first or second active area facing the semiconductor area.

12. The method of claim 6, wherein the first active area, the second active area, and the semiconductor area have the same conductivity-type impurity area.
